(19) United States
(12) Patent Application Publication
(10) Pub. No.: US 2023/0137011 A1
(43) Pub. Date: May 4, 2023

(54) Radio Frequency Chip, and Method and Apparatus for Designing Radio Frequency Chip

(71) Applicants: Beijing ESWIN Computing Technology Co., Ltd., Beijing (CN); Guangzhou Transa Semi Information Technology Co., Ltd., Guangzhou (CN)

(72) Inventors: Kaiyuan PENG, Beijing (CN); Menglin LIN, Beijing (CN)

(21) Appl. No.: 18/147,584

(22) Filed: Dec. 28, 2022

(30) Foreign Application Priority Data
May 12, 2022 (CN) 202210514419.3

(51) Int. Cl. H01F 27/34; H01F 27/28; H01F 27/40; H01Q 1/52; H01Q 1/48; G06F 30/367

(52) U.S. Cl. CPC H01F 27/34; H01F 27/28; H01F 27/40; H01Q 1/52; H01Q 1/48; G06F 30/367

(57) ABSTRACT

A radio frequency chip, and a method and apparatus for designing a radio frequency chip, which relates to the technical field of integrated circuits, with a major object to reduce the possibility of generating a parasitic capacitance between an on-chip inductor and a substrate. Herein, the radio frequency chip includes a substrate, an on-chip inductor, and an isolator between the substrate and the on-chip inductor, wherein the isolator is structured not to generate a loop induced current in a magnetic field of the on-chip inductor, and the isolator is configured to prevent a parasitic capacitance from being generated between the substrate and the on-chip inductor.

### CROSS REFERENCE TO RELATED APPLICATION

This application claims priority to Chinese Patent Application No. CN2022105144193, titled “Radio Frequency Chip, and Method and Apparatus for Designing Radio Frequency Chip” and filed to the State Patent Intellectual Property Office on the entire contents of which are incorporated herein by reference.

### TECHNICAL FIELD

The present disclosure relates to the technical field of integrated circuits, and more particularly, to a radio frequency chip, and a method and apparatus for designing a radio frequency chip.

### BACKGROUND ART

Radio frequency chips are widely used in communication devices having a wireless transceiving function, for example, in Wi-Fi (Wireless Fidelity) systems, Bluetooth systems, and mobile communication systems such as 4G (the 4th generation mobile communication technology) or 5G (the 5th generation mobile communication technology) ones. In these communication devices, radio frequency chips enable wireless transceiving and thus are one of the key units in these communication devices.

With the development of Wi-Fi, Bluetooth, mobile communication systems, and other technologies, radio frequency chips are working in a high-band-frequency environment, where a parasitic capacitance between an on-chip inductor and a substrate in a radio frequency chip is easily generated. However, the existence of the parasitic capacitance makes it possible for the noise of other circuits in the radio frequency chip to be coupled to the on-chip inductor through the substrate, which affects the performance of the on-chip inductor.

In view of the above, a solution to the problem of how to reduce the possibility of generating the parasitic capacitance between the on-chip inductor and the substrate is desirable.

### SUMMARY

The present disclosure provides a radio frequency chip, and a method and apparatus for designing a radio frequency chip, with an object to reduce the possibility of generating a parasitic capacitance between an on-chip inductor and a substrate.

In a first aspect, the present disclosure provides a radio frequency chip, including: a substrate, an on-chip inductor, and an isolator between the substrate and the on-chip inductor, wherein the isolator is structured not to generate a loop induced current in the magnetic field of the on-chip inductor;

the isolator is configured to prevent a parasitic capacitance from being generated between the substrate and the on-chip inductor.

In the radio frequency chip provided in the present disclosure, since the substrate and the on-chip inductor in the radio frequency chip are isolated by the isolator, and the isolator can prevent the parasitic capacitance from being generated between the substrate and the on-chip inductor, the possibility of generating the parasitic capacitance between the on-chip inductor and the substrate can be reduced during the use of the radio frequency chip. In addition, since the isolator is structured not to generate a loop-induced current in the magnetic field of the on-chip inductor, the isolator does not generate the loop current in the magnetic field of the on-chip inductor while preventing the parasitic capacitance from being generated between the substrate and the on-chip inductor, and thus the performance of the on-chip inductor is not affected.

In some embodiments, a first side of the isolator is opposite a second side of the on-chip inductor; a front projection of the second side of the on-chip inductor on the first side of the isolator is within or completely coincident with the first side. In the present disclosure, the front projection of the second side of the on-chip inductor on the first side of the isolator is within the first side or completely coincident with the first side, which can increase the extent to which the on-chip inductor and the substrate are isolated, prevent the on-chip inductor from facing the substrate directly in any area, and thus reduce the possibility of generating the parasitic capacitance between the on-chip inductor and the substrate.

In some embodiments, the isolator is a first planar structure provided with a plurality of notches, where the plurality of notches serve to prevent the first planar structure from generating a loop induced current in the magnetic field of the on-chip inductor. In the present disclosure, since the notch can prevent the first planar structure from generating the loop induced current in the magnetic field of the on-chip inductor, the performance of the on-chip inductor is not affected when the first planar structure prevents the parasitic capacitance from being generated between the substrate and the on-chip inductor.

In some embodiments, the isolator is a second planar structure including at least one fishbone structure; the fishbone structure includes a fishbone trunk, at least one first fishbone branch, and at least one second fishbone branch; where the at least one first fishbone branch is connected to the fishbone trunk at a first side of the fishbone trunk, the at least one second fishbone branch is connected to the fishbone trunk at a second side of the fishbone trunk, and there is no contact between any two adjacent first fishbone branches and between any two adjacent second fishbone branches. In the present disclosure, since the fishbone branches in the fishbone structure are arranged on both sides of the fishbone trunk, and there is no contact between any adjacent fishbone branches, the fishbone structure is less likely to generate the loop induced current in the magnetic field of the on-chip inductor, hence the performance of the on-chip inductor is not affected when the second planar structure prevents the parasitic capacitance from being generated between the substrate and the on-chip inductor.

In some embodiments, the radio frequency chip further includes a resistor; one end of the resistor is connected to the isolator, and the other end of the resistor is connected to a grounding end; the resistor serves to block the transmission of a noise signal from the grounding end to the isolator. In the present disclosure, when the isolator discharges electric charges acquired thereby to the grounding end, the resistor can block the transmission of the noise signal from the grounding end the isolator, thereby effectively preventing a noise of the grounding end from being transmitted into the radio frequency chip to affect the performance of the on-chip inductor and other circuits in the radio frequency chip.

In some embodiments, the radio frequency chip further includes: a support for supporting the isolator such that the isolator is positioned between the substrate and the on-chip inductor. The support in the present disclosure enables the isolator to be stably fixed between the substrate and the on-chip inductor, reducing the possibility of the collapse of the radio frequency chip.

In some embodiments, the support is polysilicon; the polysilicon fills between the on-chip inductor and the isolator and between the substrate and the isolator.

In a second aspect, the present disclosure provides a method for designing a radio frequency chip, including:

selecting an isolator for a radio frequency chip to which the isolator is to be added in response to an isolator selection instruction, wherein the isolator is a component between a substrate and an on-chip inductor of the radio frequency chip, and the isolator is structured not to generate a loop induced current in a magnetic field of the on-chip inductor and configured to prevent a parasitic capacitance from being generated between the substrate and the on-chip inductor;

generating a simulation chip model of the radio frequency chip provided with the isolator in a simulation system on the basis of the selected isolator; and

invoking the simulation system to perform a simulation test on the simulation chip model.

In the method for designing a radio frequency chip provided in the present disclosure, since the substrate and the on-chip inductor in the radio frequency chip are isolated by the isolator, and the isolator can prevent the parasitic capacitance from being generated between the substrate and the on-chip inductor, the possibility of generating the parasitic capacitance between the on-chip inductor and the substrate can be reduced during the simulation of the radio frequency chip. In addition, since the isolator is structured not to generate a loop-induced current in the magnetic field of the on-chip inductor, the isolator does not generate the loop current in the magnetic field of the on-chip inductor while preventing the parasitic capacitance from being generated between the substrate and the on-chip inductor, and thus the performance of the on-chip inductor is not affected. The use of the isolator in the radio frequency chip removes the influence of the parasitic capacitance on the performance of the radio frequency chip, a complicated simulation process is no more necessary to address the parasitic capacitance when designing a radio frequency chip, and thus the design of the radio frequency chip can be simplified.

In some embodiments, after invoking the simulation system to perform a simulation test on the simulation chip model, the method further includes: prompting that parameters need to be adjusted for the radio frequency chip when a determination is made that performance parameters resulted from the simulation test does not satisfy performance requirements. In the present disclosure, prompting that parameters need to be adjusted for the radio frequency chip can prompt and instruct a designer to adjust the design of the radio frequency chip in time, thereby improving the efficiency of designing the radio frequency chip.

In a third aspect, the present disclosure provides an apparatus for designing a radio frequency chip, including:

a selecting unit for selecting an isolator for a radio frequency chip to which the isolator is to be added in response to an isolator selection instruction, wherein the isolator is a component between a substrate and an on-chip inductor of the radio frequency chip, and the isolator is structured not to generate a loop induced current in a magnetic field of the on-chip inductor and configured to prevent a parasitic capacitance from being generated between the substrate and the on-chip inductor;

a generating unit for generating a simulation chip model of the radio frequency chip provided with the isolator in a simulation system on the basis of the selected isolator; and

an invoking unit for invoking the simulation system to perform a simulation test on the simulation chip model.

Advantageous effects of the third aspect may be understood by referring to the above description of the second aspect and will not be described in detail here.

In a fourth aspect, the present disclosure provides a communication device including the radio frequency chip as described in the first aspect above.

Advantageous effects of the fourth aspect may be understood by referring to the above description of the second aspect and will not be described in detail here.

In a fifth aspect, the present disclosure provides a computer-readable storage medium storing a set of programs, codes, or instructions, wherein the method for designing a radio frequency chip according to the second aspect is performed when the programs, codes, or instructions are run.

In a sixth aspect, the present disclosure provides a computer program product storing a set of programs, codes, or instructions, wherein the method for designing a radio frequency chip according to the second aspect is performed when the programs, codes, or instructions are run. Advantageous effects of the fifth and sixth aspects may be understood by referring to the description of the third aspect and will not be described in detail here.

### BRIEF DESCRIPTION OF THE DRAWINGS

FIG. 1 is a first block diagram of a configuration of a radio frequency chip provided by an embodiment of the present disclosure;

FIG. 2 is a first schematic diagram of an isolator provided by an embodiment of the present disclosure;

FIG. 3 is a second schematic diagram of an isolator provided by an embodiment of the present disclosure;

FIG. 4 is a third schematic diagram of an isolator provided by an embodiment of the present disclosure;

FIG. 5 is a schematic diagram showing a working mechanism of the isolator provided by an embodiment of the present disclosure;

FIG. 6 is a second block diagram of the configuration of the radio frequency chip provided by an embodiment of the present disclosure;

FIG. 7 is a flowchart of a method for designing a radio frequency chip provided by an embodiment of the present disclosure;

FIG. 8 is a first block diagram of a configuration of an apparatus for designing a radio frequency chip provided by an embodiment of the present disclosure;

FIG. 9 is a second block diagram of the configuration of the apparatus for designing a radio frequency chip provided by an embodiment of the present disclosure.

### DETAILED DESCRIPTION

Exemplary embodiments of the present disclosure will be described in more detail below with reference to the accompanying drawings. While the drawings show exemplary embodiments of the present disclosure, it is to be understood that the present disclosure may be embodied in various forms and shall not be construed as limited to the embodiments set forth herein. Rather, these embodiments are provided so that this disclosure will be thorough and complete, and will fully convey the scope of the disclosure to those skilled in the art.

With the rapid development of radio frequency communication technologies, radio frequency chips are widely used in communication devices with a wireless transceiving function, for example, in Wi-Fi systems, Bluetooth systems, and 4G or 5G mobile communication systems. In these communication devices, radio frequency chips enable wireless transceiving and thus are one of the key units in these communication devices.

In practical applications, a communication device having a wireless transceiving function can be taken as one of the above communication devices, which include the two types, namely, terminals and IoT devices. For example, the terminal may be a smart phone, a smart wearable device such as smart eyeglasses, a smart watch, and a smart bracelet, a tablet computer, a private computer, a laptop computer, a desktop computer, etc. The IoT device may be an in-vehicle device, a sensor device, an edge device, etc.

In communication devices, radio frequency chips typically operate in high-frequency-band environments, where a parasitic capacitance is easily generated between an on-chip inductor and a substrate in a radio frequency chip. The parasitic capacitance causes the following two problems: firstly, the parasitic capacitance enables the noise of other circuits in the radio frequency chip to be coupled to the on-chip inductor through the substrate, affecting the performance of the on-chip inductor; secondly, the parasitic capacitance enables the noise generated by the on-chip inductor to be coupled to other circuits in the radio frequency chip through the substrate, affecting the performance of other circuits.

To solve the above problems, embodiments of the present disclosure provide a radio frequency chip, and a method and apparatus for designing a radio frequency chip to isolate the on-chip inductor from the substrate within the radio frequency chip, thereby reducing the possibility of generating the parasitic capacitance between the on-chip inductor and the substrate. The radio frequency chip provided by the embodiments of the present disclosure can be applied to the above communication device with a wireless transceiving function, and the method and apparatus for designing a radio frequency chip provided by the embodiments of the present disclosure are used for designing the above radio frequency chip. The radio frequency chip, and the method and apparatus for designing a radio frequency chip provided by embodiments of the present disclosure are described in detail below.

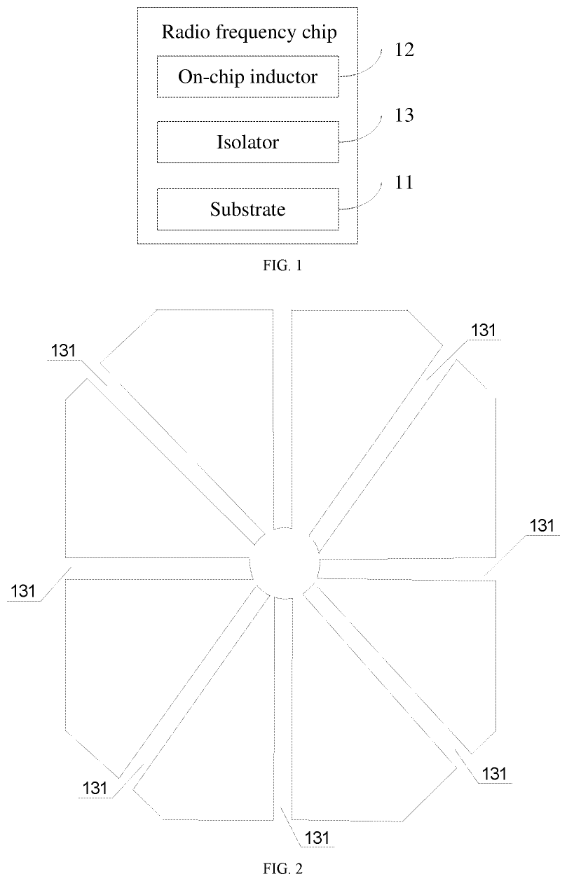

As shown in FIG. 1, the embodiment of the present disclosure provides a radio frequency chip, including a substrate 11, an on-chip inductor 12, and an isolator 13 between the substrate 11 and the on-chip inductor 12. Here, the isolator 13 is structured not to generate a loop-induced current in the magnetic field of the on-chip inductor 12. The isolator 13 is configured to prevent a parasitic capacitance from being generated between the substrate 11 and the on-chip inductor 12.

The components involved in the radio frequency chip are specifically described below.

### Substrate 11:

The substrate 11 serves as a carrier and holder in the radio frequency chip for carrying and/or holding the on-chip inductor 12, the isolator 13, and other necessary circuit structures in the radio frequency chip.

The type and shape of the substrate 11 may be determined according to specific business requirements. Illustratively, the substrate 11 is a P-shaped injected silicon substrate.

### On-Chip Inductor 12:

The on-chip inductor 12 is one of the key units in the radio frequency chip, the specific type of which can be determined according to specific business requirements. Illustratively, a differential inductor or a single-ended inductor may be taken as the on-chip inductor 12 according to the business requirements.

### Isolator 13:

The isolator 13 is configured to prevent the parasitic capacitance from being generated between the substrate 11 and the on-chip inductor 12, and the isolator 13 is provided so that, on one hand, a situation where the noise of other circuits in the radio frequency chip is coupled to the on-chip inductor 12 through the substrate 11 and affects the performance of the on-chip inductor is avoided, and on the other hand, a situation where the noise generated by the on-chip inductor 12 is coupled to other circuits in the radio frequency chip through the substrate 11 and affects the performance of the other circuits is avoided.

The isolator 13 is provided between the substrate 11 and the on-chip inductor 12 for isolating the substrate 11 from the on-chip inductor 12 and preventing parasitic capacitance from being generated between the substrate 11 and the on-chip inductor 12. To improve the isolation effect of the isolator 13, the isolator 13 needs to be configured relative to the on-chip inductor 12 such that a first side of the isolator 13 is opposite a second side of the on-chip inductor 12, and a front projection of the second side of the on-chip inductor 12 on the first side of the isolator 13 is within or completely coincident with the first side of the isolator 13. The configuration that the front projection of the second side of the on-chip inductor 12 on the first side of the isolator 13 is within or completely coincident with the first side of the isolator 13 is intended for completely isolating the on-chip inductor 12 from the substrate 11, and preventing the on-chip inductor 12 from facing the substrate 11 directly in any area thereof. The parasitic capacitance is possible to be generated between the on-chip inductor 12 and the substrate 11 if the on-chip inductor 12 faces the substrate 11 directly in an area thereof.

In practical applications, the on-chip inductor 12 may produce a magnetic field when operating, and to avoid the generation of a loop current in the isolator 13 in the magnetic field of the on-chip inductor 12 according to the Lenz's law and the influence on the performance of the on-chip inductor 11, the isolator 13 is structured not to generate a loop induced current in the magnetic field of the on-chip inductor 12.

The isolator 13 is structured not to generate the loop induced current in the magnetic field of the on-chip inductor 12. A structure of the isolator 13 is exemplified by the following two types.

In a first type, the isolator 13 is a first planar structure provided with a plurality of notches 131, where the plurality of notches 131 serve to prevent the first planar structure from generating the loop induced current in the magnetic field of the on-chip inductor 12.

The shape of the first planar structure is not limited specifically in this embodiment. In practical applications, it would be desirable enough if the first planar structure can prevent the parasitic capacitance from being generated between the substrate 11 and the on-chip inductor 12. In addition, the shape and number of the plurality of notches 131 provided in the first planar structure are not limited in this embodiment, and in practical applications, it is only necessary to ensure that the notches 131 can prevent the first planar structure from generating the loop induced current in the magnetic field of the on-chip inductor 12. Illustratively, in FIG. 2, one isolator 13 is shown, and the isolator 13 is the first planar structure provided with the plurality of notches 131, and since the plurality of notches 131 divide the first planar structure into a plurality of sections, the isolator 13 does not generate the loop induced current in the magnetic field of the on-chip inductor 12.

In a second type, the isolator 13 is a second planar structure including at least one fishbone structure 142. The fishbone structure 132 includes a fishbone trunk 1321, at least one first fishbone branch 1322, and at least one second fishbone branch 1323. Herein, the at least one first fishbone branch 1322 is connected to the fishbone trunk 1321 at a first side of the fishbone trunk 1321, the at least one second fishbone branch 1323 is connected to the fishbone trunk 1321 at a second side of the fishbone trunk 1321, and there is no contact between any two adjacent first fishbone branches 1322 and between any two adjacent second fishbone branches 1323.

The number of the fishbone structure 132 in the second planar structure is not defined specifically in this embodiment, and one or more fishbone structures 132 may be provided in the second planar structure. In addition, the number of the first fishbone branch 1322 and the second fishbone branch 1323, an angle at which the first fishbone branch 1322 and the second fishbone branch 1323 are connected to the fishbone trunk 1321, a spacing between any two adjacent first fishbone branches 1322, and a spacing between any two adjacent second fishbone branches 1323 may all depend on business requirements, and the present embodiment does not limit in this regard. Illustratively, to increase the extent to which the isolator 13 prevents the parasitic capacitance from being generated between the substrate 11 and the on-chip inductor 12, the spacing between any two adjacent first fishbone branches 1322 and the spacing between any two adjacent second fishbone branches 1323 are as narrow as possible.

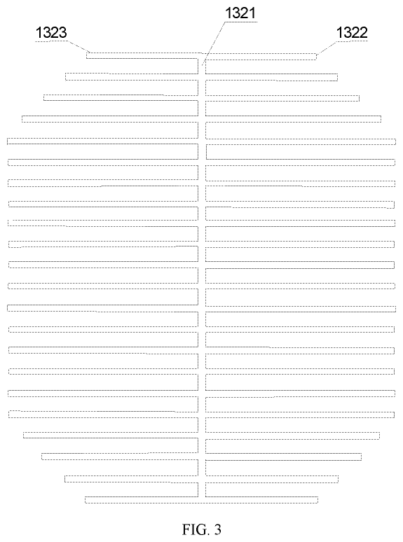

Illustratively, as shown in FIG. 3, a schematic diagram of the isolator 13, the isolator 13 is the second planar structure including the one fishbone structure 142. The fishbone structure in FIG. 3 includes one fishbone trunk 1321, a plurality of first fishbone branches 1322, and a plurality of second fishbone branches 1323. Only one of the first fishbone branches 1322 and one of the second fishbone branches 1323 are identified in FIG. 3. Herein, the plurality of first fishbone branches 1322 are connected to the fishbone trunk 1321 at one side of the fishbone trunk 1321 without contact between any adjacent first fishbone branches 1322. The plurality of second fishbone branches 1323 are connected to the fishbone trunk 1321 at the other side of the fishbone trunk 1321 without contact between any adjacent second fishbone branches 1323. The absence of contact between any two adjacent first fishbone branches 1322 and between any two adjacent second fishbone branches 1323 minimizes the generation of the loop induced current by the second planar structure in the magnetic field of the on-chip inductor 12.

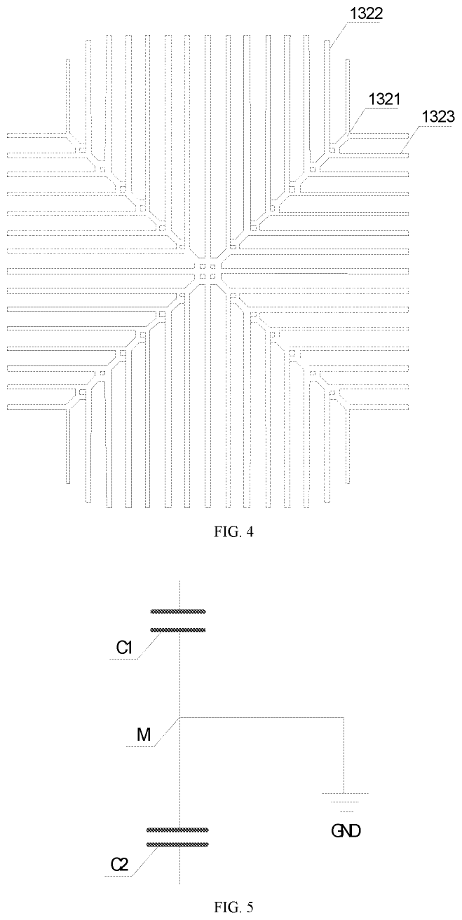

Illustratively, as shown in FIG. 4, a schematic diagram of the isolator 13, the isolator 14 is the second planar structure including four fishbone structures 132. To distinguish one from another of the four fishbone structures, two fishbone structures in FIG. 4 are indicated by dashed lines and two fishbone structures are indicated by solid lines. Each of the fishbone structures in FIG. 4 includes one fishbone trunk 1321, a plurality of first fishbone branches 1322, and a plurality of second fishbone branches 1323. For one fishbone structure, the plurality of first fishbone branches 1322 are connected to the fishbone trunk 1321 at one side of the fishbone trunk 1321 without contact between any adjacent first fishbone branches 1322. The plurality of second fishbone branches 1323 are connected to the fishbone trunk 1321 at the other side of the fishbone trunk 1321 without contact between any adjacent second fishbone branches 1323. The absence of contact between any two adjacent first fishbone branches 1322 and between any two adjacent second fishbone branches 1323 minimizes the generation of the loop induced current by the second planar structure in the magnetic field of the on-chip inductor 12.

The process by which the isolator 13 prevents the parasitic capacitance from being generated between the substrate 11 and the on-chip inductor 12 is described as follows: the isolator 13 acquires electric charges generated by the substrate 11 in an electric field and acquires electric charges generated by the on-chip inductor 12 in the electric field, and discharges the acquired electric charges, thereby preventing the parasitic capacitance from being generated between 11 and the on-chip inductor 12. Generally, the isolator 13 discharges the acquired electric charges by connecting the isolator 13 to the grounding end, and transmitting, by the isolator 13, the acquired electric charges to the grounding end when the radio frequency chip works, so as to discharge the electric charges. Such a manner can be presented in FIG. 5, where a working mechanism of the isolator 13 is shown. C1 in FIG. 5 denotes a parasitic capacitance generated by the isolator 13 and an on-chip inductor 12, and C2 denotes a parasitic capacitance generated by the isolator 13 and the substrate 11. The isolator 13 acquires electric charges generated by the substrate 11 in the electric field and acquires electric charges generated by the on-chip inductor 12 in the electric field through these two parasitic capacitances, and transmits the acquired electric charges to the grounding end through point M so as to discharge the electric charges. Point M in FIG. 4 is a connection between the isolator 13 and the grounding end GND.

In practical applications, the isolator 13 is connected to the grounding end; when the electric charges are discharged to the grounding end, if the grounding end is not provided with a noise blocking element, the noise of the grounding end is transmitted to the isolator 13 and enables the isolator 13 to affect the performance of the on-chip inductor 12 and other circuits in the radio frequency chip. Therefore, to prevent the noise of the grounding end from entering the isolator 13, as shown in FIG. 6, the radio frequency chip further includes a resistor 14. One end of the resistor 14 is connected to the isolator 13, and the other end of the resistor 13 is connected to the grounding end 15. The resistor 14 serves to block the transmission of a noise signal from the grounding end 15 to the isolator 13. In practical applications, the type of the resistor 14 is not defined specifically in this embodiment, and in principle, a resistor is desirable enough if its effect of blocking the transmission of the noise signal of the grounding end 15 meets the business requirements. Illustratively, the resistor 14 is a polysilicon resistor.

To fix the isolator 13 stably between the substrate 11 and the on-chip inductor 12 and avoid collapse of the radio frequency chip, as shown in FIG. 6, the radio frequency chip further includes a support 16. The support 16 serves to support the isolator 13 such that the isolator 13 is positioned between the substrate 11 and the on-chip inductor 12. The type of the support 16 is not specifically defined in this embodiment, and a selection of the support 16 is acceptable as long as the isolator 13 can be supported between the substrate 11 and the on-chip inductor 12 and a material of the support 16 does not affect the performance of the on-chip inductor 12 and other circuit structures in the radio frequency chip.

Illustratively, the support 16 is polysilicon. The polysilicon is filled between the on-chip inductor 12 and the isolator 13 and between the substrate 11 and the isolator 13 to support the isolator 13 between the substrate 11 and the on-chip inductor 12.

In the radio frequency chip provided in the present disclosure, since the substrate and the on-chip inductor in the radio frequency chip are isolated by the isolator, and the isolator can prevent the parasitic capacitance from being generated between the substrate and the on-chip inductor, the possibility of generating the parasitic capacitance between the on-chip inductor and the substrate can be reduced during the use of the radio frequency chip. In addition, since the isolator is structured not to generate a loop-induced current in the magnetic field of the on-chip inductor, the isolator does not generate the loop current in the magnetic field of the on-chip inductor while preventing the parasitic capacitance from being generated between the substrate and the on-chip inductor, and thus the performance of the on-chip inductor is not affected.

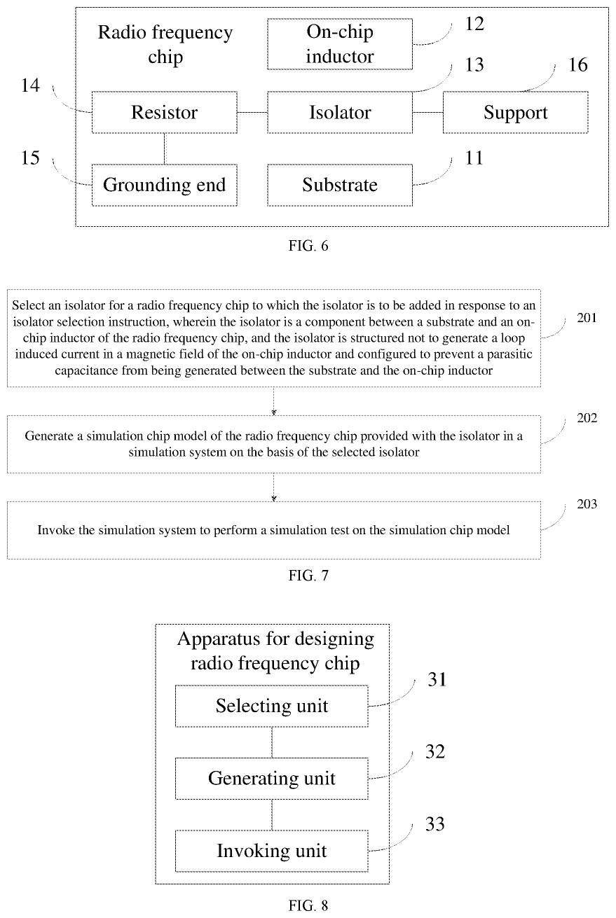

Furthermore, another embodiment of the present disclosure also provides a method for designing a radio frequency chip, by which a radio frequency chip having an isolator can be produced. The resulting radio frequency chip has a low possibility of generating a parasitic capacitance between a substrate and an on-chip inductor when the radio frequency chip is applied to a communication device because of the isolator between the substrate and the on-chip inductor, and thus the radio frequency chip can keep good performance. As shown in FIG. 7, the method for designing a radio frequency chip may include the following steps.

In step 201, an isolator is selected for a radio frequency chip to which the isolator is to be added in response to an isolator selection instruction, wherein the isolator is a component between a substrate and an on-chip inductor of the radio frequency chip, and the isolator is structured not to generate a loop induced current in a magnetic field of the on-chip inductor and configured to prevent a parasitic capacitance from being generated between the substrate and the on-chip inductor.

A parasitic capacitance is likely to be generated between the on-chip inductor and the substrate in the radio frequency chip. To reduce the influence of the parasitic capacitance on the performance of the radio frequency chip, it is necessary to select the isolator for the radio frequency chip when designing the radio frequency chip and use the isolator to reduce the possibility of easily generating the parasitic capacitance between the on-chip inductor and the substrate. In practical applications, any radio frequency chip in want of the isolator can be selected as the radio frequency chip to which the isolator is to be added. When the radio frequency chip to which the isolator is to be added is selected, the isolator selection instruction is issued for the radio frequency chip. Once the isolator selection instruction is issued, the isolator is selected for the radio frequency chip to which the isolator is to be added on the basis of the isolator selection instruction.

The isolator selection instruction may carry specification information such as the type, material, and size of the isolator, and upon the selection of the isolator, the selection is performed on the basis of the information carried by the isolator selection instruction.

In step 202, a simulation chip model of the radio frequency chip provided with the isolator is generated in a simulation system on the basis of the selected isolator.

After the isolator is selected, the simulation chip model of the radio frequency chip provided with the isolator is simulated and generated in the simulation system, and all the features of the radio frequency chip are simulated in the simulation chip model, which is the basis for performing a simulation test on the radio frequency chip.

In step 203, the simulation system is invoked to perform a simulation test on the simulation chip model.

After the simulation chip model is generated, the simulation system is invoked to perform the simulation test on the simulation chip model. The process of the simulation test is specified as follows: the simulation chip model is tested in various working scenarios to obtain performance parameters of the radio frequency chip corresponding to the simulation chip model in the various working scenarios. The resultant performance parameters are an important basis for radio frequency chip design. A determination can be made as to whether the radio frequency chip meets the present disclosure requirements according to the performance parameter. When a determination is made that the radio frequency chip does not meet the present disclosure requirements, the radio frequency chip is structurally adjusted on the basis of the performance parameters. It is to be noted that since the isolator can prevent the parasitic capacitance from being generated between the substrate and the on-chip inductor, the influence of the parasitic capacitance on the simulation can be eliminated at the time of simulation, and thus the whole simulation process can be simplified.

Furthermore, after invoking the simulation system to perform a simulation test on the simulation chip model, the method includes prompting that parameters need to be adjusted for the radio frequency chip when a determination is made that performance parameters resulting from the simulation test do not satisfy performance requirements.

A prompt of parameter adjustment for the radio frequency chip is used to remind a designer of adjusting the design of the radio frequency chip. Illustratively, the prompt of parameter adjustment for the radio frequency chip relates to parameters about the isolator, for example, if these parameters reveal that the performance of the on-chip inductor does not meet the requirements, and a determination is made that the performance parameters of the on-chip inductor do not meet the design requirements because of an improper design of the isolator, then design parameters of the isolator can be adjusted, a new simulation chip model is generated in the simulation system on the basis of the adjusted isolator, and the simulation system is invoked to perform the simulation test on the new simulation chip model. On such a basis, the above process is repeated until a determination is made that the performance parameters resulting from the simulation test meet the performance requirements.

In the method for designing a radio frequency chip provided in the present disclosure, since the substrate and the on-chip inductor in the radio frequency chip are isolated by the isolator, and the isolator can prevent the parasitic capacitance from being generated between the substrate and the on-chip inductor, the possibility of generating the parasitic capacitance between the on-chip inductor and the substrate can be reduced during the simulation of the radio frequency chip. In addition, since the isolator is structured not to generate a loop-induced current in the magnetic field of the on-chip inductor, the isolator does not generate the loop current in the magnetic field of the on-chip inductor while preventing the parasitic capacitance from being generated between the substrate and the on-chip inductor, and thus the performance of the on-chip inductor is not affected. The use of the isolator in the radio frequency chip removes the influence of the parasitic capacitance on the performance of the radio frequency chip, a complicated simulation process is no more necessary to address the parasitic capacitance when designing a radio frequency chip, and thus the design of the radio frequency chip can be simplified.

Furthermore, according to the above method embodiment, another embodiment of the present disclosure also provides an apparatus for designing a radio frequency chip, as shown in FIG. 8, the apparatus including:

a selecting unit 31 for selecting an isolator for a radio frequency chip to which the isolator is to be added in response to an isolator selection instruction, wherein the isolator is a component between a substrate and an on-chip inductor of the radio frequency chip, and the isolator is structured not to generate a loop induced current in a magnetic field of the on-chip inductor and configured to prevent a parasitic capacitance from being generated between the substrate and the on-chip inductor;

a generating unit 32 for generating a simulation chip model of the radio frequency chip provided with the isolator in a simulation system on the basis of the selected isolator; and

an invoking unit 33 for invoking the simulation system to perform a simulation test on the simulation chip model.

In the apparatus for designing a radio frequency chip provided by the embodiments of the present disclosure, since the substrate and the on-chip inductor in the radio frequency chip are isolated by the isolator, and the isolator can prevent the parasitic capacitance from being generated between the substrate and the on-chip inductor, the possibility of generating the parasitic capacitance between the on-chip inductor and the substrate can be reduced during the simulation of the radio frequency chip. In addition, since the isolator is structured not to generate a loop-induced current in the magnetic field of the on-chip inductor, the isolator does not generate the loop current in the magnetic field of the on-chip inductor while preventing the parasitic capacitance from being generated between the substrate and the on-chip inductor, and thus the performance of the on-chip inductor is not affected. The use of the isolator in the radio frequency chip removes the influence of the parasitic capacitance on the performance of the radio frequency chip, a complicated simulation process is no more necessary to address the parasitic capacitance when designing a radio frequency chip, and thus the design of the radio frequency chip can be simplified.

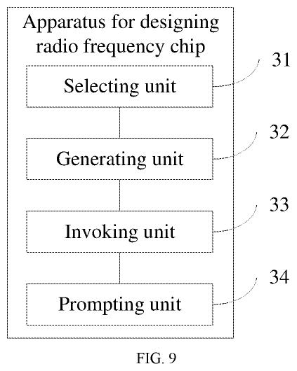

Optionally, as shown in FIG. 9, the apparatus for designing a radio frequency chip further includes: a prompting unit 34 for prompting that parameters need to be adjusted for the radio frequency chip when a determination is made that performance parameters resulting from the simulation test do not satisfy performance requirements.

In the apparatus for designing a radio frequency chip provided in the embodiments of the present disclosure, a detailed description of a method performed by each functional module can be known with reference to the detailed description of the corresponding method in the above embodiments of the method for designing a radio frequency chip, and will not be detailed here.

Furthermore, according to the above embodiments, another embodiment of the present disclosure further provides a communication device including the radio frequency chip as described above.

Advantageous effects of the communication device provided by the embodiments of the present disclosure can be known with reference to the embodiments of the radio frequency chip described above and will not be described in detail here.

Furthermore, according to the above embodiments, another embodiment of the present disclosure further provides a computer-readable storage medium storing a set of programs, codes, or instructions, wherein the method for designing a radio frequency chip as described above is performed when the programs, codes, or instructions are executed.

Furthermore, according to the above embodiments, the present disclosure provides a computer program product storing a set of programs, codes, or instructions, wherein the method for designing a radio frequency chip as described above is performed when the programs, codes, or instructions are executed.

Advantageous effects of the computer-readable storage medium and the computer program product provided by the embodiments of the present disclosure can be known with reference to the above embodiments of the method for designing a radio frequency chip and will not be described in detail here.

In the above embodiments, the description of each embodiment has its own emphasis, and reference can be made to other embodiments for a more detailed description of something not detailed in an embodiment.

It is to be understood that associated features in the method and apparatus described above may be understood by referring to one another. In addition, the terms like “first” and “second” in the above embodiments are intended to distinguish one from another of the various embodiments and do not indicate the superiority of any embodiment.

It will be clear to a person skilled in the art that, for the convenience and brevity of the description, specific working procedures of the above system, apparatus, and units may be understood by referring to corresponding procedures in the preceding method embodiments and will not be described in detail here.

The algorithms and displays presented herein are not inherently related to any particular computer, virtual system, or other devices. Various general-purpose systems may also be used with the teachings herein. The structure required to construct such a system is apparent from the above description. Further, this application is not directed to any particular programming language. It should be understood that the subject matter described herein may be implemented using a variety of programming languages and that the description above of a specific language is for the purpose of disclosing the best mode of implementing the subject matter.

Numerous specific details are set forth in the description provided herein. However, it is readily understood that embodiments of the present disclosure may be practiced without these specific details. In some instances, well-known methods, structures, and techniques are not shown in detail in order not to obscure the understanding of this description.

Moreover, those skilled in the art will appreciate that although some embodiments described herein include certain but not other features included in other embodiments, combinations of features of different embodiments are meant to be within the scope of the present disclosure and constitute different embodiments. For example, in the appended claims, any of the claimed embodiments may be used in any combination.

Various component embodiments of the present disclosure may be implemented in hardware, or in a software module running on one or more processors, or in a combination thereof. Those skilled in the art will appreciate that a microprocessor or digital signal processor (DSP) may be used in practice to implement some or all of the functions of some or all of the components of the method and apparatus for designing a radio frequency chip in accordance with embodiments of the present disclosure. The present disclosure can also be implemented as a device or means program (e.g., a computer program and a computer program product) for performing some or all of the methods described herein. Such a program implementing the present disclosure may be stored on a computer-readable medium, or maybe in the form of one or more signals. Such signals may be downloaded from the Internet, provided on a carrier signal, or provided in any other form.

It should be noted that the above embodiments illustrate rather than limit the present disclosure, and that those skilled in the art will be able to devise alternative embodiments without departing from the scope of the appended claims. In the claims, any reference signs placed between parentheses shall not be construed as limiting the claim Terms like “comprising” does not exclude the presence of elements or steps other than those listed in a claim. Articles like “a” or “an” preceding an element do not exclude the presence of a plurality of such elements. The present disclosure may be implemented by means of hardware including several distinct elements, and by means of a suitably programmed computer. In the unit claims enumerating several means, several of these means can be embodied by one hardware. Terms like “first”, “second”, and “third” do not indicate any sequence and may be interpreted as designations.

1. A radio frequency chip, comprising: a substrate, an on-chip inductor, and an isolator between the substrate and the on-chip inductor, wherein the isolator is structured not to generate a loop induced current in a magnetic field of the on-chip inductor;
the isolator is configured to prevent a parasitic capacitance from being generated between the substrate and the on-chip inductor.

2. The radio frequency chip of claim 1, wherein a first side of the isolator is opposite a second side of the on-chip inductor; a front projection of the second side of the on-chip inductor on the first side of the isolator is within or completely coincident with the first side.

3. The radio frequency chip of claim 1, wherein the isolator is a first planar structure provided with a plurality of notches, where the plurality of notches serve to prevent the first planar structure from generating a loop induced current in the magnetic field of the on-chip inductor.

4. The radio frequency chip of claim 1, wherein the isolator is a second planar structure comprising at least one fishbone structure; the fishbone structure comprises a fishbone trunk, at least one first fishbone branch, and at least one second fishbone branch; where the at least one first fishbone branch is connected to the fishbone trunk at a first side of the fishbone trunk, the at least one second fishbone branch is connected to the fishbone trunk at a second side of the fishbone trunk, and there is no contact between any two adjacent first fishbone branches and between any two adjacent second fishbone branches.

5. The radio frequency chip of claim 1, further comprising a resistor; one end of the resistor is connected to the isolator, and the other end of the resistor is connected to a grounding end; the resistor serves to block transmission of a noise signal from the grounding end to the isolator.

6. The radio frequency chip of claim 2, further comprising a resistor; one end of the resistor is connected to the isolator, and the other end of the resistor is connected to the grounding end; the resistor serves to block transmission of the noise signal from the grounding end to the isolator.

7. The radio frequency chip of claim 3, further comprising a resistor; one end of the resistor is connected to the isolator, and the other end of the resistor is connected to the grounding end; the resistor serves to block transmission of the noise signal from the grounding end to the isolator.

8. The radio frequency chip of claim 4, further comprising a resistor; one end of the resistor is connected to the isolator, and the other end of the resistor is connected to the grounding end; the resistor serves to block transmission of the noise signal from the grounding end to the isolator.

9. The radio frequency chip of claim 1, further comprising: a support for supporting the isolator such that the isolator is positioned between the substrate and the on-chip inductor.

10. The radio frequency chip of claim 2, further comprising: a support for supporting the isolator such that the isolator is positioned between the substrate and the on-chip inductor.

11. The radio frequency chip of claim 3, further comprising: a support for supporting the isolator such that the isolator is positioned between the substrate and the on-chip inductor.

12. The radio frequency chip of claim 4, further comprising: a support for supporting the isolator such that the isolator is positioned between the substrate and the on-chip inductor.

13. The radio frequency chip of claim 9, wherein the support is polysilicon; the polysilicon fills between the on-chip inductor and the isolator and between the substrate and the isolator.

14. The radio frequency chip of claim 10, wherein the support is polysilicon; the polysilicon fills between the on-chip inductor and the isolator and between the substrate and the isolator.

15. The radio frequency chip of claim 11, wherein the support is polysilicon; the polysilicon fills between the on-chip inductor and the isolator and between the substrate and the isolator.

16. The radio frequency chip of claim 12, wherein the support is polysilicon; the polysilicon fills between the on-chip inductor and the isolator and between the substrate and the isolator.

17. A method for designing a radio frequency chip, comprising:
selecting an isolator for a radio frequency chip to which the isolator is to be added in response to an isolator selection instruction, wherein the isolator is a component between a substrate and an on-chip inductor of the radio frequency chip, and the isolator is structured not to generate a loop induced current in a magnetic field of the on-chip inductor and configured to prevent a parasitic capacitance from being generated between the substrate and the on-chip inductor;
generating a simulation chip model of the radio frequency chip provided with the isolator in a simulation system on the basis of the selected isolator; and
invoking the simulation system to perform a simulation test on the simulation chip model.

18. The method of claim 17, after invoking the simulation system to perform a simulation test on the simulation chip model, further comprising:
prompting that parameters need to be adjusted for the radio frequency chip when a determination is made that performance parameters resulting from the simulation test do not satisfy performance requirements.

19. An apparatus for designing a radio frequency chip, comprising:
a selecting unit for selecting an isolator for a radio frequency chip to which the isolator is to be added in response to an isolator selection instruction, wherein the isolator is a component between a substrate and an on-chip inductor of the radio frequency chip, and the isolator is structured not to generate a loop induced current in a magnetic field of the on-chip inductor and configured to prevent a parasitic capacitance from being generated between the substrate and the on-chip inductor;
a generating unit for generating a simulation chip model of the radio frequency chip provided with the isolator in a simulation system on the basis of the selected isolator; and
an invoking unit for invoking the simulation system to perform a simulation test on the simulation chip model.
